(19) United States
(12) Patent Application Publication
(10) Pub. No.: US 2026/0190802 A1
(43) Pub. Date: Jul. 2, 2026

(54) LIGHT EMITTING DISPLAY DEVICE

(71) Applicant: LG Display Co., Ltd., Seoul (KR)

(72) Inventors: Kyuhwan LEE, Paju-si (KR); SeHong PARK, Paju-si (KR); InGoo LEE, Paju-si (KR)

(73) Assignee: LG Display Co., Ltd., Seoul (KR)

(21) Appl. No.: 19/387,321

(22) Filed: Nov. 12, 2025

(30) Foreign Application Priority Data
Dec. 30, 2024 (KR) 10-2024-0201444

(51) Int. Cl. H10K 59/80; H10K 59/124; H10K 59/38; H10K 102/00

(52) U.S. Cl. CPC H10K 59/878; H10K 59/124; H10K 59/38; H10K 59/80515; H10K 59/8052; H10K 2102/3023

(57) ABSTRACT

A light emitting display device can include a substrate, a plurality of pixels arranged on the substrate, a first planarization layer on the substrate, a second planarization on the first planarization, a slit, an anode electrode, an emission layer and a cathode electrode. Each of the pixels can have an emission area and a non-emission area. The second planarization layer can be disposed at the emission area and the slit can be disposed at a middle portion of the second planarization layer. The slit can be formed by depressing down from an upper surface of the second planarization layer. The anode electrode can be disposed on the upper surface of the second planarization layer and a bottom surface of the slit. The emission layer can be disposed on the anode electrode, the first planarization layer and the second planarization layer, while the cathode electrode is on the emission layer.

### CROSS-REFERENCE TO RELATED APPLICATIONS

This application claims priority to Korean Patent Application No. 10-2024-0201444, filed in the Republic of Korea on December 30, 2024, which is hereby expressly incorporated by reference in its entirety.

### BACKGROUND

### Field of the Invention

The present disclosure relates to a light emitting display device. In particular, the present disclosure relates to a bottom emission type light emitting display device having micro mirrors to enhance the light extraction efficiency.

### Discussion of the Related Art

Among the display devices, light emitting display devices can have the advantages of a wide viewing angle, excellent contrast, and fast response speed. The light emitting element used in a light emitting display device can have a light emitting layer made of an organic or inorganic material disposed between the anode electrode and the cathode electrode.

In the light emitting element, holes are supplied from the anode electrode and electrons are supplied from the cathode electrode, and then the electrons and holes combine at the emission layer to generate excitons. As the excitons change from the excited state to the ground state, the fluorescent molecules in the emission layer can emit light to express color.

Some of the light emitted from the emission layer of the light emitting display device may not be emitted to the outside and can be lost due to a total reflection within the electrode layer having a high refractive index, or due to a total reflection occurring at the interface between the emission layer and the electrodes and/or the interface between the substrate and the air. This can result in a problem or limitation of reduced light extraction efficiency.

To overcome or address these problems, methods are being developed to improve the light extraction efficiency of light emitting devices by forming microlenses or microcavity structures inside the devices. However, although these structures can improve the luminous efficiency of light emitted in the vertical direction of the display device, they may not extract light emitted in the horizontal direction to the vertical direction. Therefore, existing methods can have limitations in improving light extraction efficiency.

### SUMMARY OF THE DISCLOSURE

A purpose of the present disclosure, as for solving or addressing the problems described above or associated with the related art, is to provide a bottom emission type light emitting display device that maximizes light extraction efficiency by extracting light generated from the emission layer to the outside, which can otherwise be trapped inside the device and disappear due to total reflection.

Another purpose of the present disclosure is to provide a bottom emission type light emitting display device that improves brightness (or luminance) degradation rate and light extraction efficiency by arranging a micro mirror structure on the edge of the light emitting area to maximize the area of the light emitting area. In particular, the present disclosure provides a bottom emission type light emitting display device that improves light extraction efficiency and enhances brightness per power consumption by extracting light that can be extinguished by an electric field from the central portion of the anode electrode to the outside.

Another purpose of the present disclosure is to provide a light emitting display device including a slit form by recessing a middle portion of the emission area, so to have micro mirror structures not only at the edge portion of the emission area but also at the middle portion of the emission area. Accordingly, the present disclosure can provide a bottom emission type display device with improved light extraction efficiency by reducing the amount of lights that can be trapped inside the light emitting diode due to the total reflection at the middle portion of the anode electrode. Furthermore, the present disclosure can provide a bottom emission type display device in which the anode electrode is extended to the bottom and/or inclined portion of the slit to maximize the area of the emission area, thereby improving light extraction efficiency and enhancing brightness (or luminance) per power consumption.

In order to accomplish the above mentioned purposes of the present disclosure, a light emitting display device according to aspects of the present disclosure comprises a substrate, a plurality of pixels, a first planarization layer on the substrate, a second planarization layer on the first planarization layer, a slit, an anode electrode, an emission layer and a cathode electrode. The plurality of pixels are arrayed on the substrate, each of the pixels having an emission area and a non-emission area. The second planarization layer is disposed at the emission area. The slit is disposed at a middle portion of the second planarization layer. The slit is formed by depressing down from an upper surface of the second planarization layer. The anode electrode is disposed on the upper surface of the second planarization layer and a bottom surface of the slit. The emission layer is on the anode electrode, the first planarization layer and the second planarization layer. The cathode electrode is on the emission layer.

The light emitting display device according to aspects of the present disclosure can have a structure in which almost all of the lights emitted from the emission layer can be extracted to the outside without being trapped and extinguished inside of the device, thereby providing a bottom emission type light emitting display device with maximized light extraction efficiency.

The light emitting display device according to aspects of the present disclosure can provide a bottom emission type light emitting display device that minimizes non-emission areas and improve light extraction efficiency by arranging micro mirrors (or reflectors) without using a bank covering the circumferences of the pixel electrode.

With the micro-mirror structure formed at the edge of the anode electrode, the light emitting display device according to aspects of the present disclosure can further extract lights that would otherwise be lost within the light emitting diode (or, within the anode electrode). In particular, by implementing a structure in which the anode electrode is divided by a slit so that lights that can be lost within the light emitting diode (or, within the anode electrode) in the central portion of the pixel can be also extracted to the outside, the light extraction efficiency can be further improved.

In addition, by extending the anode electrode to the bottom surface and/or the inclined surface of the slit, the light emitting display device according to aspects of the present disclosure can improve the emission area ratio by increasing the area ratio occupied by the anode electrode within the pixel. Accordingly, the light emitting display device can provide higher brightness with the same power consumption, or uses lower power consumption to provide the same brightness. Therefore, the light emitting display device according to aspects of the present disclosure can be driven at low power consumption.

The effects that can be obtained from the present disclosure are not limited to the effects mentioned above, and other effects that are not mentioned can be clearly understood by those skilled in the art to which this disclosure belongs from the description below.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram illustrating a schematic structure of a light emitting display device according to one or more embodiments of the present disclosure.

FIG. 2 is a circuit diagram illustrating a structure of one pixel included in the light emitting display device according to an example of the present disclosure.

FIG. 3 is a plan view illustrating an arrangement structure of the pixels arrayed in one unit-pixel of the light emitting display device according to an example of the present disclosure.

FIG. 4 is an enlarged cross-sectional view, taken along line I-I’ in FIG. 3, for illustrating the structure of a light emitting display device according to an example of the present disclosure.

FIG. 5 is an enlarged cross-sectional view, taken along line II-II’ in FIG. 3, for illustrating light paths in a light emitting display device according to an example of the present disclosure.

FIG. 6 is an enlarged cross-sectional view, taken along line II-II’ of FIG. 3, illustrating a structure of a light emitting display device according to a first embodiment of the present disclosure.

FIG. 7 is an enlarged plan view illustrating a structure of a light emitting display device according to a second embodiment of the present disclosure.

FIG. 8 is an enlarged cross-sectional view, taken along line III-III’ of FIG. 7, illustrating a structure of a light emitting display device according to the second embodiment of the present disclosure.

FIG. 9 is an enlarged cross-sectional view, taken along line III-III’ of FIG. 7, illustrating a structure of a light emitting display device according to a third embodiment of the present disclosure.

FIG. 10 is an enlarged plan view illustrating a structure of a light emitting display device according to a fourth embodiment of the present disclosure.

FIG. 11 is an enlarged cross-sectional view, taken along line IV-IV’ of FIG. 10, illustrating a structure of a light emitting display device according to the fourth embodiment of the present disclosure.

FIG. 12 is an enlarged plan view illustrating a structure of a light emitting display device according to a fifth embodiment of the present disclosure.

FIG. 13 is an enlarged cross-sectional view, taken along line V-V’ of FIG. 12, illustrating a structure of a light emitting display device according to the fifth embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the disclosure unless otherwise specified. In the following description, where the detailed description of the relevant known function or configuration can unnecessarily obscure an important point of the present disclosure, a detailed description of such known function or configuration can be omitted.

Reference will now be made in detail to the example embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms such as “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third element or layer can be interposed therebetween. Further, if a first element is described as positioned “on” a second element, it does not necessarily mean that the first element is positioned above the second element in the drawing. The upper part and the lower part of an object concerned can be changed depending on the orientation of the object. Consequently, where a first element is described as positioned “on” a second element, the first element can be positioned “below” the second element or “above” the second element in the drawings or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms such as “first,” “second,” and the like can be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) can be used. These terms are used merely to distinguish one element from another, and not to define a particular nature, order, sequence, or number of the elements. Where an element is described as being “linked”, “coupled,” or “connected” to another element, that element can be directly or indirectly connected to that other element unless otherwise specified. It is to be understood that additional element or elements can be “interposed” between the two elements that are described as “linked,” “connected,” or “coupled” to each other.

To elaborate, as used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The term "coupled" and "in contact" should be interpreted in the same manner.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. Further, the term “can” fully encompasses all the meanings and coverages of the term “may” and vice versa.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Hereinafter, a display apparatus according to embodiments of the present disclosure will be described in detail with reference to the attached drawings. All the components of each display apparatus/device according to all embodiments of the present disclosure are operatively coupled and configured. Wherever possible, the same reference numbers will be used throughout the drawings to refer to the same or like parts.

Hereinafter, referring to the drawings, the present disclosure according to embodiments of the present disclosure will be explained.

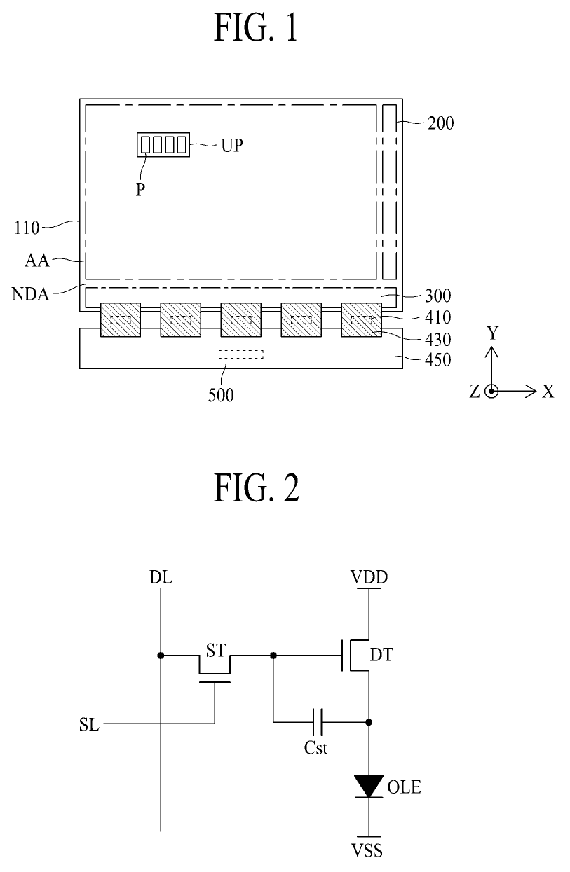

FIG. 1 is a diagram illustrating a schematic structure of a light emitting display device according to one or more embodiments of the present disclosure. In FIG. 1, an X-axis refers to the direction parallel to a scan line, a Y-axis refers to the direction of a data line, and a Z-axis refers to the thickness direction of the light emitting display device.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 can include an electrical insulating material or a flexible material. The substrate 110 can be made of a glass, a metal or a plastic, but it is not limited thereto. When the light emitting display device is a flexible display, the substrate 110 can be made of the flexible material such as plastic. For example, the substrate 110 can include a transparent polyimide material.

The substrate 110 can include a display area AA (or active area) and a non-display area NDA (or non-active area). The display area AA, which is an area for representing the video images, can be defined as the majority middle area of the substrate 110, but it is not limited thereto. In the display area AA, a plurality of scan lines (or gate lines), a plurality of data lines and a plurality of unit pixels UP can be formed or disposed. The unit pixels UP are arrayed in a matrix manner. Each of unit pixels UP can include a plurality of pixels P. Each of pixels P includes the scan line and the data line, respectively. Each of the pixels P has an emission area and a non-emission area.

The non-display area NDA, which is an area not representing the video images, can be defined at the circumference areas of the substrate 110 surrounding all or some of the display area AA. In the non-display area NDA, the gate driver 200 and the pad portion 300 can be formed or disposed.

The gate driver 200 can supply the scan (or gate) signals to the scan lines according to the gate control signal input through the pad portion 300 from the timing controller 500. The gate driver 200 can be formed at the non-display area NDA at any one outside of the display area AA on the substrate 110, as a GIP (Gate driver In Panel) type. GIP type means that the gate driver 200 is directly formed on the substrate 110. For example, the gate driver 200 can be configured as a shift resistor, and the GIP type refers to a structure in which transistors for the shift resistor of the gate driver 200 are directly formed on the substrate 110.

The pad portion 300 can supply data signals to data lines according to a data control signal input from the timing controller 500. The pad portion 300 can be formed as a driving chip and mounted on the flexible circuit film 430. The flexible circuit film 430 can be attached to the non-display area NDA of one edge of the display area AA of the substrate 110.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be installed on the flexible circuit film 430 as a COF (chip on film) or COP (chip on plastic) type.

The flexible circuit film 430 can include a plurality of first link lines connecting the pad portion 300 to the source driving IC 410, and a plurality of second link lines connecting the pad portion 300 to the circuit board 450. The flexible circuit film 430 can be attached on the pad portion 300 using an anisotropic conducting film, so that the pad portion 300 can be connected to the first link lines of the flexible circuit film 430.

The circuit board 450 can be attached to the flexible circuit film 430. The circuit board 450 can include a plurality of circuits implemented as the driving chips. For example, the circuit board 450 can be a printed circuit board or a flexible printed circuit board. The circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be formed as one chip with the source driving IC 410 and mounted on the substrate 110.

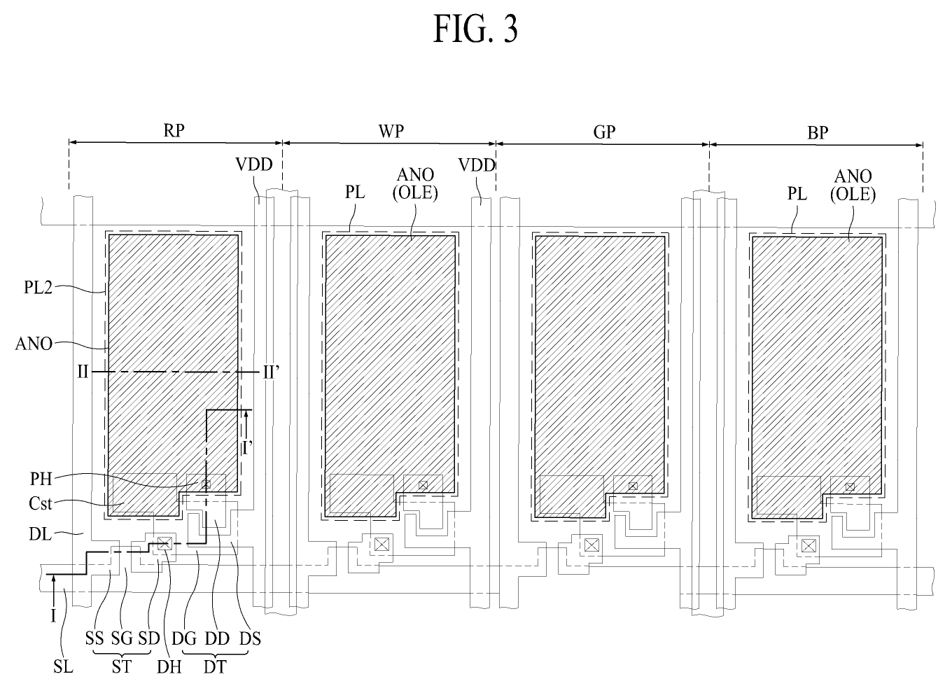

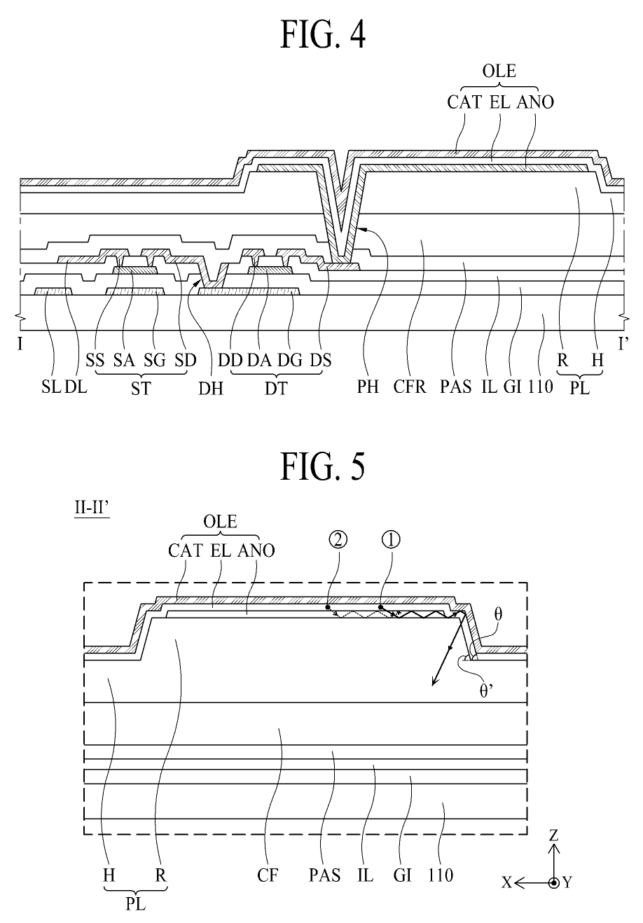

Hereinafter, referring to FIGS. 2 to 4, one or more embodiments of the present disclosure will be explained. Particularly, FIG. 2 is a circuit diagram illustrating a structure of one pixel included in the light emitting display device according to an example of the present disclosure. FIG. 3 is a plan view illustrating an arrangement structure of the pixels arrayed in a unit-pixel of the light emitting display device according to an example of the present disclosure. FIG. 4 is an enlarged cross-sectional view along to cutting line I-I’ in FIG. 3, for illustrating the structure of a light emitting display device according to an example of the present disclosure.

Referring to FIGS. 2 to 4, a light emitting display device includes a plurality of unit pixels UP in a matrix manner. Each unit pixel UP of the light emitting display device can include three pixels P or four pixels P. For example, one unit pixel P can include a red pixel RP, a green pixel GP and a blue pixel BP. For another example, as shown in FIG. 3, one unit pixel UP can include a red pixel RP, a white pixel WP, a green pixel GP, and a blue pixel BP.

One pixel P of the light emitting display device, i.e., any one among red pixel RP, white pixel WP, green pixel GP and blue pixel BP, can be defined by a scan line SL, a data line DL and a driving current line VDD. Any one pixel of the light emitting display device can include a switching thin film transistor ST, a driving thin film transistor DT, a light emitting diode OLE, and a capacitor Cst. The driving current line VDD can be supplied with a high-level voltage for driving the light emitting diode OLE.

In the following description referring to FIG. 3, one pixel P is explained as having a data line DL at the left side and a driving current line VDD at the right side. However, it is not limited thereto. The structure of pixel P can be various. For example, in one unit-pixel including four pixels P, the driving current lines VDD can be disposed, respectively, at left side and right side of the unit pixel UP. Further, a reference line can be disposed between a white pixel WP and a green pixel GP. In addition, a data line DL can be disposed at each left side of each of the pixels P.

The switching thin film transistor ST can be disposed at a location where the scan line SL and the data line DL intersect. The switching thin film transistor ST can include a gate electrode SG, a semiconductor layer SA, a source electrode SS and a drain electrode SD. The gate electrode SG can be connected to the scan line SL. The source electrode SS can be connected to the data line DL, and the drain electrode SD can be connected to the driving thin film transistor DT. The semiconductor layer SA can be disposed on a gate insulating layer GI as overlapping with the gate electrode SG. The portion of the semiconductor layer SA overlapping the gate electrode SG can be defined as a channel region.

An intermediate insulating layer IL can be deposited on the semiconductor layer SA. The source electrode SS and the drain electrode SD can be formed on the intermediate insulating layer IL. The source electrode SS can be connected to one side of the semiconductor layer SA via one contact hole formed at the intermediate insulating layer IL. The drain electrode SD can be connected to another side of the semiconductor layer SA via another contact dhole formed at the intermediate insulating layer IL. The switching thin film transistor ST can select a pixel P to be driven by applying a data signal to the driving thin film transistor DT.

The driving thin film transistor DT can drive the light emitting diode OLE of the pixel selected by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be connected to the drain electrode SD of the switching thin film transistor ST via a drain contact hole DH penetrating the gate insulating layer GI covering the gate electrode DG. The drain electrode DD can be connected to the driving current line VDD, and the source electrode DS can be connected to an anode electrode ANO of the light emitting diode OLE. The capacitor Cst can be disposed between the gate electrode DG of the driving thin film transistor DT and the anode electrode ANO of the light emitting diode OLE.

The intermediate insulating layer IL can be deposited on the semiconductor layer DA. The source electrode DS and the drain electrode DD can be formed on the intermediate insulating layer IL. The source electrode DS can be connected to one side of the semiconductor layer DA via one contact hole formed at the intermediate insulating layer IL. The drain electrode DD can be connected to another side of the semiconductor layer DA via another contact hole formed at the intermediate insulating layer IL.

The driving thin film transistor DT can be disposed between the driving current line VDD and the light emitting diode OLE. The driving thin film transistor DT can control the amount of current flowing from the driving current line VDD to the light emitting diode OLE according to the magnitude of the voltage of the gate electrode DG connected to the drain electrode SD of the switching thin film transistor ST.

The light emitting diode OLE can include an anode electrode ANO, an emission layer EL and a cathode electrode CAT. The light emitting diode OLE can emit lights in response to an electric current controlled by the driving thin film transistor DT. In detail, since the amount of light emitted can be adjusted according to the current controlled by the driving thin film transistor DT, the brightness of the light emitting display device can be controlled. The anode electrode ANO of the light emitting diode OLE can be connected to the source electrode DS of the driving thin film transistor DT, and the cathode electrode CAT can be connected to a low voltage line VSS to which a low potential voltage is applied. The light emitting diode OLE can be driven by the difference between a low-potential voltage and a high-potential voltage controlled by a driving thin film transistor DT.

A passivation layer PAS is deposited on the surface of the substrate 110 having the thin film transistors ST and DT. The passivation layer PAS can include an inorganic material such as silicon oxide (SiOx) or silicon nitride (SiNx). The thin layers configuring the thin film transistors ST and DT formed on the substrate 110 can be called as a ‘driving element layer.’ For example, from a metal layer of the scan line SL and the gate electrodes SG and DG to the passivation layer PAS covering the thin film transistors ST and DT can be defined as the driving element layer.

A color filter CF (see FIG. 5) can be formed on the passivation layer PAS. The color filter CF can be disposed on each pixel P. For example, the color filter can include a red color filter CFR disposed at the red pixel RP, a green color filter disposed at the green pixel GP, and a blue color filter disposed at the blue pixel BP. Color filter may not be disposed at the white pixel WP.

In FIG. 4, the color filter CFR is described as having a structure that extends from the emission area to the non-emission area. However, it is not limited thereto, the color filter CF can be formed as corresponding to each of the emission areas.

A planarization layer PL can be deposited on the color filter CF. The planarization layer PL can be a thin film for making the surface of the substrate 110 on which thin film transistors ST and DT are formed flat. To make the height difference even, the planarization layer PL can be formed of an organic material.

A pixel contact hole PH for exposing a portion of the source electrode DS of the driving thin film transistor DT can be formed as penetrating the passivation layer PAS, the color filter CF and the planarization layer PL. An anode electrode ANO can be formed on the planarization layer PL. The anode electrode ANO can be connected to the source electrode DS of the driving thin film transistor DT via the pixel contact hole PH.

The planarization layer PL can have a level difference. For example, the planarization layer PL can be patterned using an anode electrode ANO as a mask. As a result, the planarization layer PL can have a structure in which the planarization layer PL can protrude upward, and the anode electrode ANO is formed on the protruded planarization layer PL. FIG. 4 shows that the protrusion portion R of the planarization layer PL can be formed as covering the pixel contact hole PH. However, it is not limited thereto, the protrusion portion R of the planarization layer PL may not cover the pixel contact hole PH. In this case, the circumferential portions of the pixel contact hole PH can be included in the non-emission area.

The anode electrode ANO can have different material depending on the emission type of the light emitting diode OLE. For the bottom emission type in which the light emitting diode OLE emits toward the substrate 110, the anode electrode ANO can be formed of a transparent conductive material. For the top emission type in which the light emitting diode OLE emits upward opposing the substrate 110, the anode electrode ANO can be formed of a metal material having excellent light reflectance. In this case, the anode electrode ANO can have a structure in which a transparent conductive layer and a metal layer are stacked.

For the bottom emission type, the anode electrode ANO can be made of a transparent conductive material (TCO) or semi-transparent conductive material. For instance, the anode electrode ANO can be made of a transparent conductive material such as indium tin oxide (ITO), indium zinc oxide (IZO) or indium zinc tin oxide (IZTO). Otherwise, the anode electrode ANO can be made of a semi-transparent layer of magnesium (Mg), silver (Ag) or an alloy of magnesium (Mg) and silver (Ag) with a thickness of less than 100nm. The anode electrode ANO can be called as a first electrode or a transparent electrode.

An emission layer EL can be deposited on the anode electrode ANO. The emission layer EL can be disposed on the entire surface of the substrate 110 as one sheet type covering continuously the upper surface of the substrate 110. The emission layer EL can include various functional layers stacked each other. For example, the emission layer EL can include a hole functional layer, an organic emission layer, and an electron functional layer. Each of the hole functional layer and the electron functional layer can be deposited on the substrate 110 as continuous sheet type. The organic emission layer can have a sheet shape between the hole functional layer and the electron functional layer. However, it is not limited thereto. The organic emission layer can be disposed as separated as corresponding to each emission area of each pixel P.

In addition, the emission layer EL can include two or more emission portions for emitting white color light. For example, the emission layer EL can have a tandem structure in which a first emission layer and a second emission layer are vertically stacked for emitting white color light by mixing a first color light and a second color light. However, it is not limited thereto, the vertically stacked emission portions can include three or four layers.

A cathode electrode CAT can be deposited on the emission layer EL. The cathode electrode CAT can be disposed as a thin layer shape continuously spread on the entire surface of the substrate 110. The stacked structure of the anode electrode ANO, the emission layer EL and the cathode electrode CAT can configure the light emitting diode OLE.

The cathode electrode CAT can be made of a metal material having excellent light reflectance. For example, the cathode electrode CAT can be formed of a metal material with excellent light reflectance with a thickness of at least 2,000Å to 3,000Å (200nm to 300nm). Here, the metal material having excellent light reflectance can include aluminum (Al), magnesium (Mg), calcium (Ca), silver (Ag) or alloy of them (e.g., aluminum-magnesium alloy (AlMg)). For another example, the cathode electrode CAT can include thin metal layer having high reflectance such as stack of aluminum and titanium (Ti/Al/Ti), stack of aluminum and indium tin oxide (ITO/Al/ITO), silver alloy, or stack of silver alloy and indium tin oxide (ITO/Ag alloy/ITO). Here, silver alloy can be an alloy of silver (Ag), palladium (Pd) and copper (Cu). The cathode electrode CAT can be called as a second electrode, reflection electrode, or counter electrode.

The stacked structure of the anode electrode ANO, the emission layer EL and the cathode electrode CAT can configure the light emitting diode OLE. The light emitting display device according to the present disclosure can have a structure in which each of light emitting diode OLE is disposed on the planarization layer PL patterned with protruding island shape within the pixel P. From the planarization layer PL deposited on the driving element layer to the cathode electrode CAT of the light emitting diode OLE can be called as a ‘light emitting element layer.’ The driving element layer can be disposed under the color filter CF.

In detail, within each pixel P, a planarization layer PL is applied over the entire surface of the substrate 110, and has a protruding portion in the shape of an island with a certain thickness. The anode electrode ANO is formed on the upper surface of the protruding portion of the planarization layer PL. The emission layer EL can be deposited to cover the upper surface of the planarization layer PL having steps and the upper surface of the anode electrode ANO. The cathode electrode CAT can be also deposited with the same profile as the emission layer EL. As a result, the cathode electrode CAT can have a cap, ‘∩’, shape facing downward. Since the cathode electrode CAT can be made of a metal material with excellent light reflectance, the cathode electrode CAT can have a structure in which the cap shaped micro mirrors are formed along the protruding portion of the planarization layer PL.

In the case of the bottom emission type, there can be a disadvantage in that the area ratio of the aperture area to the pixel area can be relatively smaller than top emission type, due to the thin film transistor ST and DT, capacitor Cst, the scan line SL, the data line DL and the driving current line VDD. The light emitting display device according to the present disclosure can provide a structure equipped with a micro mirror so that light generated from the emission layer can be provided toward the substrate 110 placed underneath without loss even though the aperture area is small.

Hereinafter, referring to FIG. 5, the mechanism for enhancing the light extraction efficiency by the micro mirror will be explained. FIG. 5 is an enlarged cross-sectional view along to cutting line II-II’ in FIG. 3, for illustrating light paths in a light emitting display device according to an example of the present disclosure.

Referring to FIG. 5, it will be explained the optical path ① for light emitted from the emission layer EL at the edge region of the anode electrode ANO. Lights emitted from the emission layer EL can be transmitted as a spherical wave. Lights can be emitted in all directions 360 degrees on the cross-sectional view. Among the lights, the light emitted to the top direction can be reflected by the cathode electrode CAT and travel downward. For example, most of all lights generated from the emission layer EL can be radiated in a 180-degree downward direction. These lights can be incident into the anode electrode ANO. Since the anode electrode ANO is made of a transparent conductive material, 60% to 70% of the lights can pass through the anode electrode ANO, pass through the color filter CF placed underneath, and be emitted outside the substate 110.

Further, the anode electrode ANO can be a transparent conductive material with a refractive index of 2.0 to 2.3. The upper surface of the anode electrode ANO is in contact with the emission layer EL, and the bottom surface is in contact with the planarization layer PL. The emission layer EL and the planarization layer PL can have a refractive index of 1.3 to 1.5. As a result, a structure can be formed in which an anode electrode ANO with a high refractive index is interposed between two low refractive layers. Therefore, among the lights incident into the anode electrode ANO, 30% to 40% of the lights corresponding to the total reflection condition can be propagated in the horizontal direction (e.g., X-axis direction) inside the anode electrode ANO.

According to the material of the emission layer EL, the refractive index of the emission layer EL can be similar to the refractive index of the anode electrode ANO. In this case, among the lights emitted from the emission layer EL, the lights totally reflected at the interface between the anode electrode ANO and the planarization layer PL can be trapped between the cathode electrode CAT and the planarization layer PL, so these lights can propagate in the horizontal direction (X-axis direction).

Lights propagating horizontally within the anode electrode ANO, or between the cathode electrode CAT and the planarization layer PL can be emitted from the end of the anode electrode ANO and be reflected by the cathode electrode CAT having the micro mirror structure to go downward. When there is no micro mirror structure formed by the protrusion of the planarization layer PL, the lights can be propagated horizontally and extinguished. However, according to this structure, the lights can be extracted downward by the micro mirror, thereby improving the light extraction efficiency.

Here, it is explained that light propagating in the horizontal direction can propagate while repeating the total reflection process inside the anode electrode ANO. However, it is not limited thereto. The lights propagating in the horizontal direction can propagate while repeating the total reflection process inside the element including the anode electrode ANO and emission layer EL, i.e., between the cathode electrode CAT and the planarization layer PL. For convenience, in this disclosure, it is explained that the light can be totally reflected inside the light emitting diode OLE and can be propagate in the horizontal direction,

Here, in order to ensure that the lights reflected by the cathode electrode CAT having a micro mirror structure can be emitted to the downward direction properly, it is necessary to adjust the angle of the inclination of the cathode electrode CAT deposited on the etched side where the step of the planarization layer PL is formed. For example, the angle θ of the inclined surface of the cathode electrode CAT with respect to the horizontal surface of the substrate 110 can preferably be in the range of 50 degree to 80 degree. Since the cathode electrode CAT is deposited along the step shape of the planarization layer PL, the inclination angle θ of the cathode electrode CAT can be substantially equal to the side wall inclination angle θ’ by the protrusion portion R in the planarization layer PL. Therefore, it is preferable to form the inclination angle θ’ between the flat portion H and the protrusion portion R of the planarization layer PL to be 50 degree to 80 degree.

The light emitting display device according to the present disclosure can include the cathode electrode CAT having the micro mirror structure according to the shape of the planarization layer PL having a protrusion portion R extruded as an island shape from the flat portion H. Therefore, the light extraction efficiency can be improved by extracting the light that can be extinguished inside the light emitting diode OLE among the lights generated from the emission layer EL.

Here, for convenience of explanation, based on one pixel, the planarization layer PL can be described as a structure in which a protrusion portion R is formed on the flat portion. However, as considering the structure in which a large number of pixels are arranged in a matrix manner, the planarization layer PL can also be described as having a structure in which protrusion portions R and depression portions (corresponding to the flat portions H) are repeatedly arranged. For example, the flat portion H can be called a depression portion. In this case, the protrusion portions can correspond to the emission areas within each pixel, and the depressed portions can correspond to the non-emission areas surrounding the emission areas.

The light emitting display device having the micro mirror structure described above can extract the lights that would otherwise be trapped and extinguished within the anode electrode ANO to the outside of the anode electrode ANO. However, the lights emitted from the emission layer EL at the central region of the anode electrode ANO may not be extracted to the outside.

Hereinafter, it is explained about the optical path ② for light emitted from the emission layer EL at the central region of the light emitting diode OLE on the plan view. Lights generated from the emission layer EL can be radiated 180 degree downward by the same mechanism as described above. Since the anode electrode ANO is made of a transparent conductive material, 60% to 70% of the lights can pass through the anode electrode ANO, pass through the color filter CF placed underneath, and then be emitted outside the substrate 110.

However, among the lights incident into the anode electrode ANO, 30% to 40% of the lights that meet the total reflection condition can be propagated in the horizontal direction (X-axis direction) inside the anode electrode ANO (or, inside the light emitting diode OLE). In particular, the lights generated at the central region of the pixel can undergo a total reflection process inside the anode electrode ANO, so that the length of the optical path ② propagating light can be much longer than the length of the optical path ① described above. Therefore, the light can be dissipated as heat energy inside the anode electrode ANO before being emitted through the end of the anode electrode ANO. In general, when lights propagate over a length of 20㎛ or more inside the anode electrode ANO, the lights can be extinguished or annihilated.

Hereinafter, various embodiments of the present disclosure will be described, in which lights emitted from an emission layer EL in the middle portion (on plan view) of the light emitting diode OLE in a light emitting display device according to the present disclosure can be extracted to the outside before being lost or extinguished.

In the following explanation, the description for driving element layer which is a common element will not be duplicated. Further, the configuration of the driving element layer is not limited to the explanation mentioned as referring to FIGS. 2 to 4. The configuration of the thin film transistors ST and DT can have any one structure of top gate structure, bottom gate structure and double gate structure. The thin film transistors ST and DT can include oxide semiconductor material. For example, the material for the semiconductor layers SA and DA can include a metal oxide material such as indium gallium zinc oxide (IGZO). However, it is not limited thereto, the semiconductor layers SA and DA can include any one of an amorphous silicon (a-Si), a polycrystalline silicon (Poly Si), or a low temperature polycrystalline silicon (LTPS).

In addition, the arrangement of the signal lines including scan line SL, data line DL and driving current line VDD can be varied. Other signal lines including reference line can be further included. In the following description, drawing numeric symbols which are shown in the drawings but not explained can be referred to the description of the drawing numeric symbols in FIGS. 2 to 4.

### First Embodiment

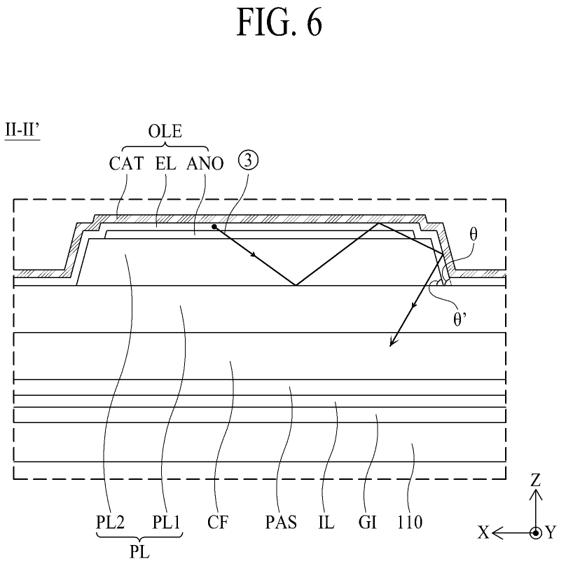

Hereinafter, referring to FIG. 6, it will be explained a structure of a light emitting display device according to the first embodiment of the present disclosure. FIG. 6 is an enlarged cross-sectional view, taken along line II-II’ of FIG. 3, illustrating a structure of a light emitting display device according to the first embodiment of the present disclosure.

Referring to FIG. 6, a gate insulating layer GI, an intermediate insulating layer IL and a passivation layer PAS can be sequentially stacked on a substrate 110. A color filter CF can be disposed on the passivation layer PAS. A planarization layer PL can be disposed on the color filter CF. The planarization layer PL can include a first planarization layer PL1 and a second planarization layer PL2 sequentially stacked. The first planarization layer PL1 can be deposited on the color filter CF as covering entire surface of the substrate 110 with a predetermined thickness. The second planarization layer PL2 can be formed as an island shape only at a location corresponding to the emission area where the anode electrode ANO is disposed within a pixel P. For example, the second planarization layer PL2 can have an island shape protruding or extracting on the first planarization layer PL1.

The emission area can mean the area where the anode electrode ANO is disposed. For example, the emission area can mean that the area where the light emitting diode OLE is formed by sequentially stacking the anode electrode ANO, the emission layer EL and the cathode electrode CAT. The present disclosure can have a feature in which light can be provided by reflecting at a portion of the cathode electrode CAT corresponding to the sidewall of the second planarization layer PL2. Therefore, the area where the second planarization layer PL2 is formed to form the micro mirror structure can be included into the emission area. The circumferential area of the emission area can be defined as the non-emission area. For example, the area where the second planarization layer PL2 does not exist but only the first planarization layer PL1 exists can be defined as the non-emission area.

Here, the sidewall inclined angle θ’ of the second planarization layer PL2 having a protruded shape (or island shape) on the first planarization layer PL1 can be same with the sidewall inclined angle θ’ described with FIG. 5. Similarly, the inclined angleθ of the cathode electrode CAT deposited on the first planarization layer PL1 and the second planarization layer PL2 can be substantially the same with the sidewall inclined angle θ’ of the second planarization layer PL2 described with FIG. 5.

The first embodiment can have a feature in which the second planarization layer PL2 in contact with the anode electrode ANO can include a transparent organic material having refractive index that is the same as or at most 0.2 lower than the refractive index of the anode electrode ANO, in order to minimize the amount of lights lost by the total reflection process inside the light emitting diode OLE.

For example, the anode electrode ANO can have a refractive index selected one from 2.0 to 2.3. The second planarization layer PL2 can have a refractive index of 1.8 to 2.0, which is the same as or about within 0.2 different from the refractive index of the anode electrode ANO. Meanwhile, the first planarization layer PL1 can have a refractive index of 1.3 to 1.5, which is at least0.5 lower than that of the second planarization layer PL2.

In this case, the light emitted from the emission layer EL can propagate with a manner of light path ③ in FIG. 6. Lights generated from the emission layer EL can be radiated 180 degrees downward by the same mechanism as described above. Since the anode electrode ANO is made of a transparent conductive material and the second planarization layer PL2 has a similar refractive index with the anode electrode ANO, 90% to 98% of the lights can pass through the anode electrode ANO and the second planarization layer PL2. The lights passing through the second planarization layer PL2 can enter into the first planarization layer PL1. As the first planarization layer PL1 has a refractive index of 1.4 to 1.5, 60% to 70% of the incident lights into the first planarization layer PL1 can pass through the first planarization layer PL1, can pass through the color filter CF placed underneath, and then be emitted outside the substrate 110.

However, among the lights passing through the second planarization layer PL2, 30% to 40% of the lights that meet the total reflection condition at the interface between the second planarization layer PL2 and the first planarization layer PL1 can be re-entered into the anode electrode ANO, and then can be totally reflected at the upper surface of the anode electrode ANO or reflected by the cathode electrode CAT.

According to light path ③shown in FIG. 6, unlike the light paths ① and ② shown in FIG. 5, the space where light emitted from the emission layer EL is totally reflected can be expanded, and the number of times for total reflection can be significantly reduced, due to the second planarization layer PL2 having a thickness of 1~1.5㎛. As a result, most of the lights emitted from the middle portion of the pixel and totally reflected may be not trapped inside the light emitting diode OLE but can pass through the interface of the light emitting diode OLE with the second planarization layer PL2. The light totally reflected at the upper surface of the first planarization layer PL1 among the lights passing through the second planarization layer PL2 can be reflected by the cathode electrode CAT having the micro-mirror structure and then can go to downward direction.

The light emitting display device according to the first embodiment can extract almost of all lights generated from the emission layer EL, due to the second planarization layer PL protruded as an island shape and the micro-mirror structure formed by the shape of the second planarization layer PL2. Accordingly, the light extraction efficiency can be further increased than the structure shown in FIG. 5. In particular, since the second planarization layer PL2 can have a refractive index same as the anode electrode ANO or slightly lower than the anode electrode ANO, the amount of the lights that can be trapped and lost inside the light emitting diode OLE can be minimized, so the light extraction efficiency can be enhanced.

### Second Embodiment

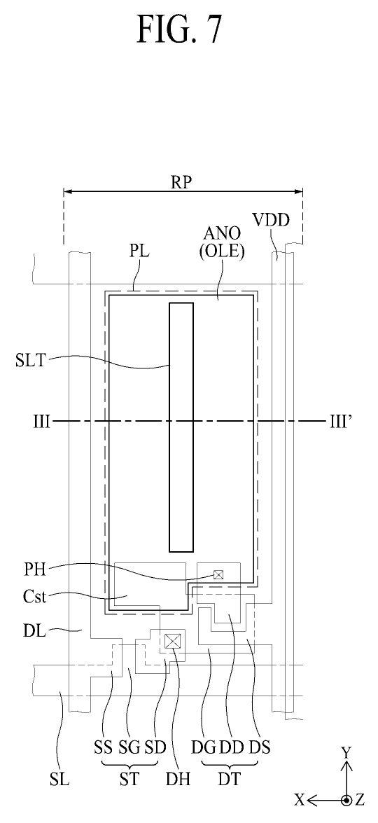

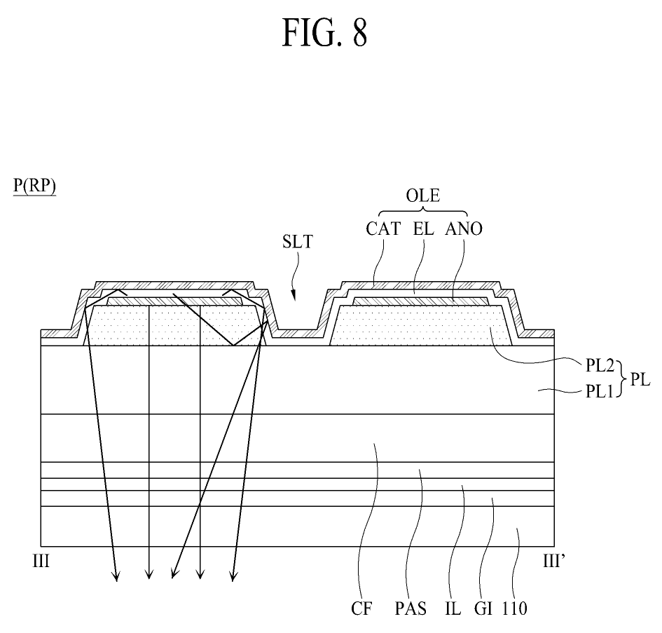

Hereinafter, referring to FIGS. 7 and 8, a structure of a light emitting display device according to the second embodiment of the present disclosure will be explained. FIG. 7 is an enlarged plan view illustrating a structure of a light emitting display device according to the second embodiment of the present disclosure. FIG. 8 is an enlarged cross-sectional view, taken along line III-III’ of FIG. 7, illustrating a structure of a light emitting display device according to the second embodiment of the present disclosure.

Referring to FIG. 7, the light emitting display device according to the second embodiment of the present disclosure can include a slit SLT having a rectangular shape which has long length along the vertical direction (Y-axis direction) and short width along the horizontal direction (X-axis direction) at a middle portion (or middle portion on plan view) of the anode electrode ANO in the red pixel RP. In FIG. 7, one slit SLT can be disposed at the middle portion of the anode electrode ANO, so the anode electrode ANO can be divided into the left portion and the right portion. However, it is not limited thereto, the slit can be disposed with different manner. FIG. 7 show the slit SLT is disposed in the red pixel RP, not limited thereto, but the slit SLT can be further disposed in the green pixel GP, the blue pixel BP and the white pixel WP with the same manner.

For another example, a plurality of slits SLT (e.g., two, three, four or five slits) can be parallelly arrayed with a predetermined gap therebetween along the horizontal direction (X-axis direction) in the anode electrode ANO. For other example, the slit SLT can have a rectangular shape which has long length along the horizontal direction (X-axis direction) and can be disposed at middle portion of the anode electrode ANO. Further, a plurality of slits SLT can be arrayed along vertical direction (Y-axis direction) with a predetermined gap therebetween. However, it is not limited thereto, the slit SLT can be disposed in ‘X’ shape or ‘+’ shape.

Referring to FIG. 8, the light emitting display device according to the second embodiment of the present disclosure can include a gate insulating layer GI, an intermediate insulating layer IL and a passivation layer PAS sequentially stacked on a substrate 110. A color filter CF can be disposed on the passivation layer PAS. A planarization layer PL can be disposed on the color filter CF.

The planarization layer PL can include a first planarization layer PL1 and a second planarization layer PL2. The first planarization layer PL1 can be disposed as covering entire surface of the substrate 110. The second planarization layer PL2 can be disposed at the emission area of the pixel P. The second planarization layer PL2 can have an island shape protruded on the upper surface of the first planarization layer PL1. The upper surface of the second planarization layer PL2 can be located at higher position than the upper surface of the first planarization layer PL1.

The second planarization layer PL2 in one pixel P can have a shape divided into two portions by a slit SLT. However, referring to FIG. 7, the upper side and lower side of the slit SLT may not divide the second planarization layer PL2. For example, at the upper side and the lower side of the pixel P, the second planarization layer PL2 can be connected as one body. The bottom surface of the slit SLT formed at the second planarization layer PL2 can be the upper surface of the first planarization layer PL1. However, it is not limited thereto. The bottom surface of the slit SLT can be located at the position higher than the upper surface of the first planarization layer PL1. In this case, the bottom surface of the slit SLT can be a bottom surface of the etched second planarization layer PL2, and the upper surface of the first planarization layer PL1 may not exposed by the slit SLT. For another example, by further etching the first planarization layer PL1 with some depth, the bottom surface of the slit SLT can be located at the etched position of the first planarization layer PL1.

An anode electrode ANO can be disposed on the upper surface of the second planarization layer PL2. In particular, the anode electrode ANO may not be disposed within the slit SLT. FIG. 8 shows that the anode electrode ANO can be divided into two portions by the slit SLT. However, as shown in FIG. 7, by placing at a certain distance from the upper and lower sides of the anode electrode ANO, the slit SLT can disposed within an area of the anode electrode ANO. Therefore, the anode electrode ANO may not be divided into two portions by the slit SLT, but can be physically and electrically connected in one pixel P.

An emission layer EL can be disposed on the first planarization layer PL1, the second planarization layer PL2 and the anode electrode ANO. The emission layer EL can cover an upper surface of the first planarization layer PL1, a sidewall of the second planarization layer PL2 and an upper surface of the anode electrode ANO. A cathode electrode CAT can be disposed on the emission layer EL. The cathode electrode CAT can surface-contact to the emission layer EL. Therefore, the emission layer EL and the cathode electrode CAT can be deposited along the cross-sectional profile of the first planarization layer PL1 and the second planarization layer PL2. Therefore, at the stepped portion due to the thickness difference between the first planarization layer PL1 and the second planarization layer PL2, the cathode electrode CAT can form the micro-mirror structure. In particular, the micro-mirror structure can be formed at each of two portions of the second planarization layer PL2 divided by the slit SLT, so there are two micro-mirrors in one pixel P in the second embodiment.

The second planarization layer PL2 can have higher refractive index than the first planarization layer PL1. Alternatively, the first planarization layer PL1 and the second planarization layer PL2 can include a material having a same refractive index. For example, the anode electrode can have a refractive index of 2.0 to 2.3. The second planarization layer PL2 can have a refractive index of 1.8 to 2.0 which is same as that of the anode electrode ANO or within 0.2 different from that of the anode electrode ANO. Meanwhile, the first planarization layer PL1 can be made of a transparent organic material having a refractive index of 1.3 to 1.5, which is at least 0.5 lower than that of the second planarization layer PL2.

The lights generated from the emission layer EL can be radiated 180 degrees downward by the same mechanism as explained in the first embodiment. The anode electrode ANO can be made of a transparent conductive material and the second planarization layer PL2 can have a similar refractive index with the anode electrode ANO. Therefore, most lights generated from the emission layer EL and incident into the anode electrode ANO can enter into the second planarization layer PL2.

Since the refractive index of the second planarization layer PL2 can be slightly lower than the anode electrode ANO, some of lights can be totally reflected at the interface between the anode electrode ANO and the second planarization layer PL2. These totally reflected lights, as the light path ① shown in FIG. 5, can be reflected by the micro-mirror structure formed at the edge portion of the anode electrode ANO and the slit SLT, and then can radiated out to the color filter CF.

The light path through which light emitted from the emission layer EL is extracted to the outside is depicted by arrows in FIG. 8. In FIG. 8, for convenience, the light extraction path is shown in the micro-mirror structure formed at the left side, but the light extraction path also exists in the same manner in the micro-mirror structure formed at the right side.

Among the lights emitted from the emission layer EL at the middle portion of the anode electrode ANO, 20% to 30% of the lights can propagate laterally (horizontally or in the X-axis direction) and then disappear while repeating the total reflection process inside the light emitting diode OLE (see optical path ② in FIG. 5). The second embodiment can have a feature that the second planarization layer PL2 can be formed of a material of which refractive index different from that of the anode electrode ANO is within 0.2. Accordingly, most of all lights entering into the anode electrode ANO can incident into the second planarization layer PL2 and then can go out through the color filter CF.

For the case that a slit SLT is not prepared, the lights generated from the middle portion of the pixel P, trapped inside the light emitting diode OLE and propagated in lateral direction by the total reflection can have long optical path, so the lights can be lost before the lights reach to the micro-mirror (referring to optical path ② of FIG. 5). However, for the case of the second embodiment, the pixel P is divided by the slit SLT, so the optical path of the lights propagated in lateral direction in the light emitting diode OLE can be shortened. Therefore, before being lost as heat energy, the lights can be extracted outside by the micro-mirror formed at the slit SLT.

Here, the light emitting diode OLE is not formed where the slit SLT is formed, because the anode electrode ANO is not disposed where the slit SLT is formed. Therefore, the area where the slit SLT is formed can be included in the non-emission area. Meanwhile, the cathode electrode CAT is formed at the inclined sidewall of slit SLT to form the micro-mirror structure. Therefore, the inclined sidewall of the slit SLT can be included in the emission area.

Among the lights incident into the second planarization layer PL2, 30% to 40% of lights satisfying the total reflection condition at the interface between the first planarization layer PL1 and the second planarization layer PL2 can re-enter into the anode electrode ANO, and then can be reflected by the cathode electrode CAT disposed over the anode electrode ANO. In this process, for most of the lights, the total reflection angle between the first planarization layer PL1 and the second planarization layer PL2 can be broken by the micro-mirror structure, so the lights can be incident into the first planarization layer PL1. After that, the lights can pass through the first planarization layer PL1 and the color filter CF disposed thereunder, then can be radiated outside the substrate 110.

In the light emitting display device according to the second embodiment, the lights generated from the emission layer EL can be extracted by the cathode electrode CAT having the micro-mirror structure formed by the second planarization layer PL2 extruded as an island shape, so the light extraction efficiency can be increased. In particular, as the second planarization layer PL2 can have a refractive index the same as or slightly less than the anode electrode ANO, the amount of trapped lights inside the light emitting diode OLE can be minimized, so the light extraction efficiency can be enhanced.

Further, by forming a slit SLT at the middle portion of the second planarization layer PL2, a plurality of micro-mirror structures can be formed. The slit SLT can be formed by depressing down from an upper surface of the second planarization layer PL2. As a result, it can be configured so that lights generated from the emission layer EL is extracted to the outside by the micro-mirror structure before being trapped inside the light emitting diode OLE due to total reflection conditions and lost as heat energy.

### Third Embodiment

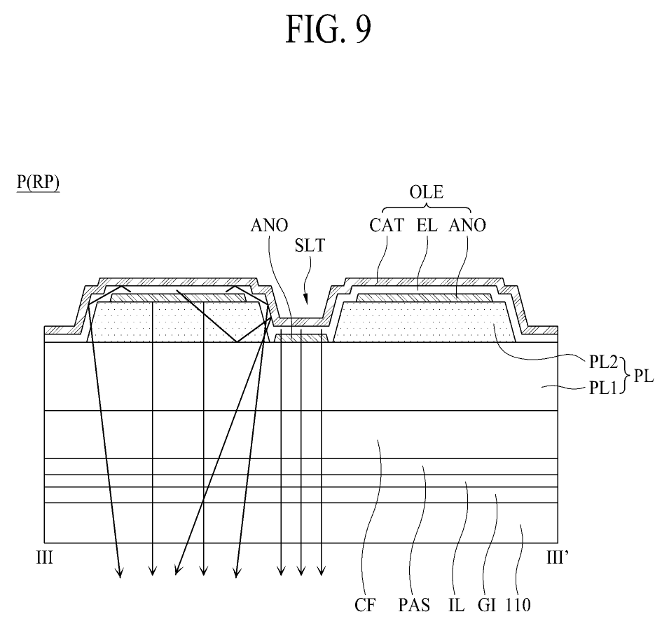

Hereinafter, referring to FIG. 7 and FIG. 9, a light emitting display device according to the third embodiment will be explained. FIG. 9 is an enlarged cross-sectional view, taken along line III-III’ of FIG. 7, illustrating a structure of a light emitting display device according to the third embodiment of the present disclosure.

Referring to FIG. 9, a light emitting display device according to the third embodiment can have very similar structure to that of the second embodiment. For a different feature, the light emitting display device according to the third embodiment can have a structure in which anode electrode ANO is further disposed where the slit SLT is formed.

With the structure of the second embodiment, the anode electrode ANO is not disposed where the slit SLT is formed, so the area of slit SLT can be the non-emission area. On the other hand, in the third embodiment, the anode electrode ANO can be disposed on the upper surface of the first planarization layer PL1 which can be corresponding to the bottom surface of the slit SLT. Referring to FIG. 7 showing a plan view, the anode electrode ANO disposed on the bottom surface of the slit SLT can be physically and electrically connected to the anode electrode ANO disposed on the upper surface of the second planarization layer PL2 via the upper surface and the bottom surface of the slit SLT.

As a result, at the slit SLT, a light emitting diode OLE can be formed by stacking the anode electrode ANO, the emission layer EL and the cathode electrode CAT sequentially. Therefore, the area of a slit SLT can be included into the emission area, so the emission area can be further enlarged.

The third embodiment can provide a bottom emission type light emitting display device having enhanced light extraction efficiency due to the micro-mirror structure. Further, in the light emitting display device according to the third embodiment, the slit SLT can be disposed at the middle portion of the pixel P, so that the lights which can be trapped inside the light emitting diode OLE and lost as heat energy can be extracted to the outside. Accordingly, the light extraction efficiency can be increased. By configuring the area of slit SLT to have light emitting diode OLE, the emission area can be increased.

### Fourth Embodiment

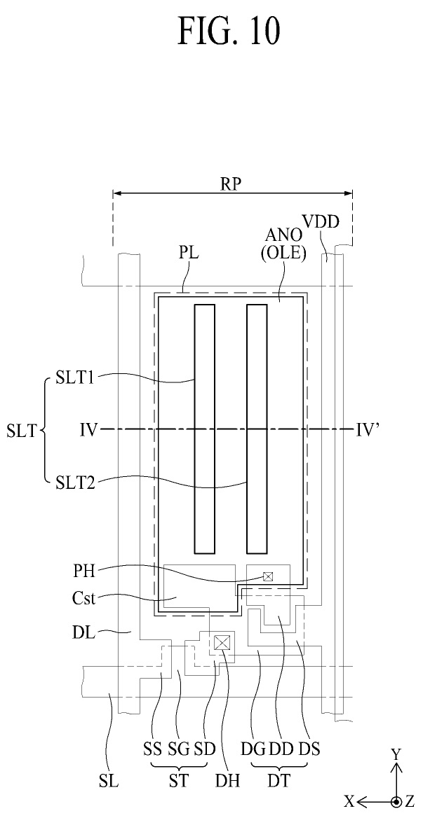

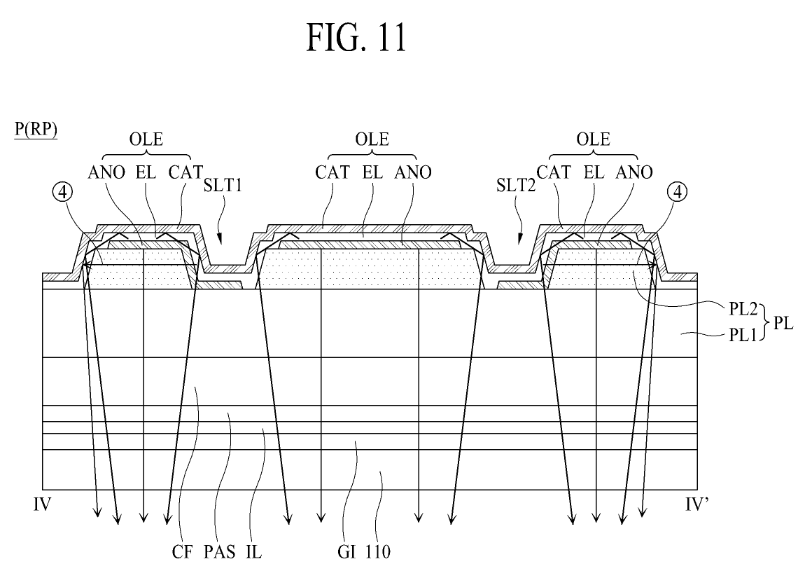

Hereinafter, referring to FIG. 10 and FIG. 11, a light emitting display device according to the fourth embodiment will be explained. FIG. 10 is an enlarged plan view illustrating a structure of a light emitting display device according to the fourth embodiment of the present disclosure. FIG. 11 is an enlarged cross-sectional view, taken along line IV-IV’ of FIG. 10, illustrating a structure of a light emitting display device according to the fourth embodiment of the present disclosure. The cutting line IV-IV’ has a ‘⊂’ shape or ‘C’ shape.

Referring to FIG. 10, a light emitting display device according to the fourth embodiment of the present disclosure can include a pixel P having a rectangular shape of which vertical side is longer than lateral side. In particular, at the middle portion of the pixel P (or middle portion of the anode electrode ANO), two slits SLT can be disposed. Each of the slit SLT has a rectangular shape of which lateral side length along X-axis is shorter than the vertical side width along Y-axis. For example, a first slit SLT1 and a second slit SLT2 can be disposed as being separated with a predetermined distance (or gap).

However, it is not limited thereto. The number of the slit SLT disposed inside the pixel P can be any one of 2 ~5. Further, even though FIG. 10 shows the red pixel RP, other pixels can include same slits SLT as the red pixel RP. The structures of other portions of the pixel P except the slit SLT can be the same as the pixel P described with FIG. 3, so the same explanation will not be duplicated.

Referring to FIG. 11, the light emitting display device according to the fourth embodiment can include a gate insulating layer GI, an intermediate insulating layer IL and a passivation layer PAS sequentially stacked on a substrate 110. A color filter CF can be disposed on the passivation layer PAS. A planarization layer PL can be disposed on the color filter CF.

The planarization layer PL can include a first planarization layer PL1 and a second planarization layer PL2. The first planarization layer PL1 can be disposed over entire surface of the substrate 110, and the second planarization layer PL2 can be disposed within emission area of the pixel P. The second planarization layer PL2 can have an island shape extruded (or protruded) on the upper surface of the first planarization layer PL1. The upper surface of the second planarization layer PL2 can be disposed at higher position than the upper surface of the first planarization layer PL1.

The second planarization layer PL2 can have three regions in the pixel P divided by a plurality of sub-slits arrayed with a predetermined gap, for example, the first slit SLT1 and the second slit SLT2. However, referring to FIG. 10, at the left side portion and the right side portion of the pixel P, the second planarization layer PL2 may not be divided by the first slit SLT1 and the second slit SLT2. For example, the second planarization layer PL2 can be continuously disposed at the left side and the right side (or a first side and a second side) of the pixel P (an upper side and a lower side of the pixel P can be called as a third side and a fourth side). The bottom surfaces of the first slit SLT1 and the second slit SLT2 can be corresponding to the upper surface of the first planarization layer PL1. The first slit SLT1 and the second slit SLT2 can expose the upper surface of the first planarization layer PL1. However, it is not limited thereto, the bottom surfaces of the first slit SLT1 and the second slit SLT2 can be located at slightly higher position than the upper surface of the first planarization layer PL1. In this case, the first planarization layer PL1 may not be exposed by the first slit SLT1 and the second slit SLT2. The bottom surfaces of the first slit SLT1 and the second slit SLT2 can be the bottom surfaces formed by depressing or recessing the second planarization layer PL2. For another example, the bottom surfaces of the first slit SLT1 and the second slit SLT2 can be located under the upper surface of the first planarization layer PL1 by etching the first planarization layer PL1 with a depth.

An anode electrode ANO can be disposed on the upper surface of the second planarization layer PL2. Further, the anode electrode ANO can be disposed at the bottom surfaces of the first slit SLT1 and the second slit SLT2. As shown in FIG. 10, on the plan view, the first slit SLT1 and the second slit SLT2 can be disposed as being apart from the left side and right side with the predetermined distances, respectively, within inside area of the anode electrode ANO. Therefore, entire portions of the anode electrode ANO can be electrically connected within a pixel P.

As the anode electrode ANO is disposed in the first slit SLT1 and the second slit SLT2, the light emitting diode OLE can be formed in the first slit SLT1 and the second slit SLT2. Therefore, the first slit SLT1 and the second slit SLT2 can be included in the emission area. By comparing the case in which the anode electrode ANO is not disposed in the first slit SLT1 and the second slit SLT2, the light emitting display device according to the fourth embodiment can have enhanced emission area.

For example, the anode electrode ANO can be disposed at the bottom surface of the first slit SLT1, extending along the left etched side wall (the left etched side wall disposed at a first side of the bottom surface and the right etched side wall disposed at a second side of the bottom surface facing the first side of each slit can be called a first sidewall and a second sidewall respectively) of the first slit SLT1 formed at the second planarization layer PL2, and then reaching to the upper surface of the second planarization layer PL2. Further, the anode electrode ANO can be disposed at the bottom surface of the second slit SLT2, extending along the right etched side wall of the second slit SLT2 formed at the second planarization layer PL2, and then reaching to the upper surface of the second planarization layer PL2.

An emission layer EL can be disposed on the first planarization layer PL1, the second planarization layer PL2 and the anode electrode ANO. A cathode electrode CAT can be disposed on the emission layer EL. The cathode electrode CAT can be in surface contact with the emission layer EL. Therefore, the emission layer EL and the cathode electrode CAT can be stacked along the cross-sectional profile of the first planarization layer PL1and the second planarization layer PL2. Accordingly, at the step different portions of the first planarization layer PL1 and the second planarization layer PL2, the cathode electrode CAT can form a micro-mirror structure. In particular, each of the three regions of the second planarization layer PL2 divided by the first slit SLT1 and the second slit SLT2 can have micro-mirror, so the light emitting display device according to the fourth embodiment can include three micro mirror structures, within the pixel P.

The second planarization layer PL2 can have higher refractive index than the first planarization layer PL1. For example, the anode electrode can have a refractive index of 2.0 to 2.3. The second planarization layer PL2 can have a refractive index of 1.8 to 2.0 which is same as that of the anode electrode ANO or within 0.2 different from that of the anode electrode ANO. Meanwhile, the first planarization layer PL1 can be made of a transparent organic material having a refractive index of 1.3 to 1.5, which is at least 0.5 lower than that of the second planarization layer PL2.

The lights generated from the emission layer EL can be radiated 180 degrees downward by the same mechanism as explained in the first embodiment. The anode electrode ANO can be made of a transparent conductive material and the second planarization layer PL2 can have a similar refractive index with the anode electrode ANO. Therefore, most lights generated from the emission layer EL and incident into the anode electrode ANO can enter into the second planarization layer PL2.

Since the refractive index of the second planarization layer PL2 can be slightly lower than the anode electrode ANO, some of lights can be totally reflected at the interface between the anode electrode ANO and the second planarization layer PL2. These totally reflected lights can be reflected by the micro-mirror structures formed at the edge portion of the anode electrode ANO, the first slit SLT1 and the second slit SLT2, and then can radiated out to the color filter CF.

Among the lights emitted from the emission layer EL at the middle portion of the anode electrode ANO, 20% to 30% of the lights can propagate laterally (horizontally or in the X-axis direction) and then disappear while repeating the total reflection process inside the light emitting diode OLE (see optical path ② in FIG. 5). The fourth embodiment can have a feature that the second planarization layer PL2 can be formed of a material of which refractive index different from that of the anode electrode ANO is within 0.2. Accordingly, most of all lights entering into the anode electrode ANO can incident into the second planarization layer PL2 and then can go out through the color filter CF. The optical path of the light extracted to out of the substrate is shown as arrow line in FIG. 11.

For the case that a slit SLT is not prepared, the lights generated from the middle portion of the pixel P, trapped inside the light emitting diode OLE and propagated in lateral direction by the total reflection can have long optical path, so the lights can be lost before the lights reach to the micro-mirror (referring to optical path ② of FIG. 5). However, for the case of the fourth embodiment, the pixel P is divided by the slit SLT, so the optical path of the lights propagated in lateral direction in the light emitting diode OLE can be shortened. Therefore, before being lost as heat energy, the lights can be extracted outside by the micro-mirror formed at the slit SLT.

Among the lights incident into the second planarization layer PL2, 30% to 40% of lights satisfying the total reflection condition at the interface between the first planarization layer PL1 and the second planarization layer PL2 can re-enter into the anode electrode ANO, and then can be reflected by the cathode electrode CAT disposed over the anode electrode ANO. In this process, for most of the lights, the total reflection angle between the first planarization layer PL1 and the second planarization layer PL2 can be broken by the micro-mirror structure, so the lights can be incident into the first planarization layer PL1. After that, the lights can pass through the first planarization layer PL1 and the color filter CF disposed thereunder, then can be radiated outside the substrate 110. For example, lights generated from the emission layer EL disposed at the first sidewall of the slit SLT on the anode electrode ANO can pass through the second planarization layer PL2, be reflected by the cathode electrode CAT facing the first sidewall and then pass through the first planarization layer PL1 and then be radiated out of the substrate 110.

Further, in the light emitting display device according to the fourth embodiment, the anode electrode ANO can be disposed as starting from the upper surface of the second planarization layer PL2, extending along the sidewalls of the first slit SLT1 and the second slit SLT2, and then to the bottom surfaces of the first slit SLT1 and the second slit SLT2. Therefore, the light emitting diode OLE can be formed at the sidewalls of the first slit SLT1 and the second slit SLT2 by stacking the anode electrode ANO, the emission layer EL and the cathode electrode CAT. For example, the light can be provided from the sidewalls of the first slit SLT1 and the second slit SLT2.

The light generated from the sidewalls of the first slit SLT1 and the second slit SLT2 can pass through the second planarization layer PL2, and propagate to the opposite sidewall of the second planarization layer PL2. The sidewall of the second planarization layer PL2 can have the cathode electrode CAT so it can form the micro-mirror structure. Therefore, the lights generated from the sidewall of the first slit SLT1 and the second slit SLT2 can be reflected by the micro-mirror structure so emitted out of the substrate 110, shown as the optical path ④ in FIG. 11.

In the light emitting display device according to the fourth embodiment, the lights generated from the emission layer EL can be extracted by the cathode electrode CAT having the micro-mirror structure formed by the second planarization layer PL2 extruded as an island shape, so the light extraction efficiency can be increased. In particular, as the second planarization layer PL2 can have a refractive index the same as or slightly less than the anode electrode ANO, the amount of trapped lights inside the light emitting diode OLE can be minimized, so the light extraction efficiency can be enhanced.

Further, by forming a slit SLT at the middle portion of the second planarization layer PL2, a plurality of micro-mirror structures having the length or width smaller than the length or width of the pixel can be formed. As a result, it can be configured so that lights generated from the emission layer EL is extracted to the outside by the micro-mirror structure before being trapped inside the light emitting diode OLE due to total reflection conditions and lost as heat energy.

### Fifth Embodiment

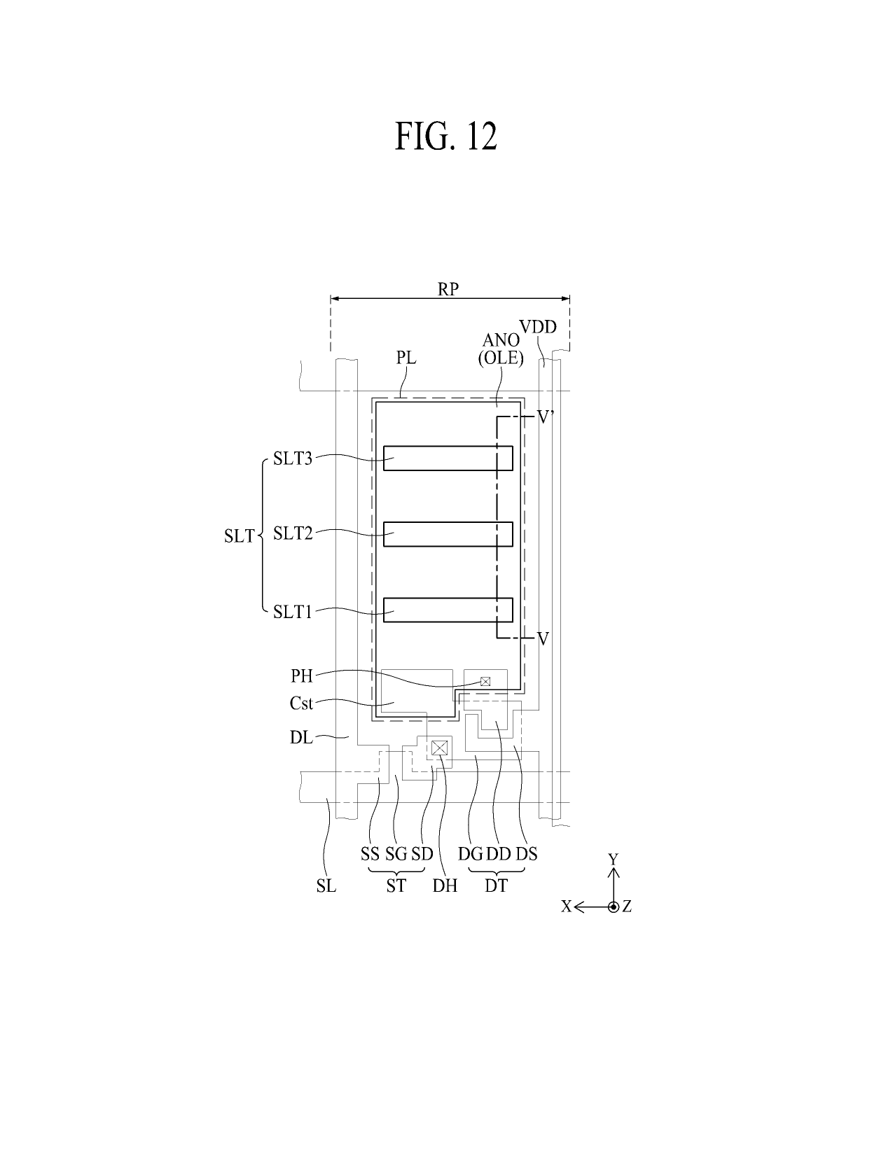

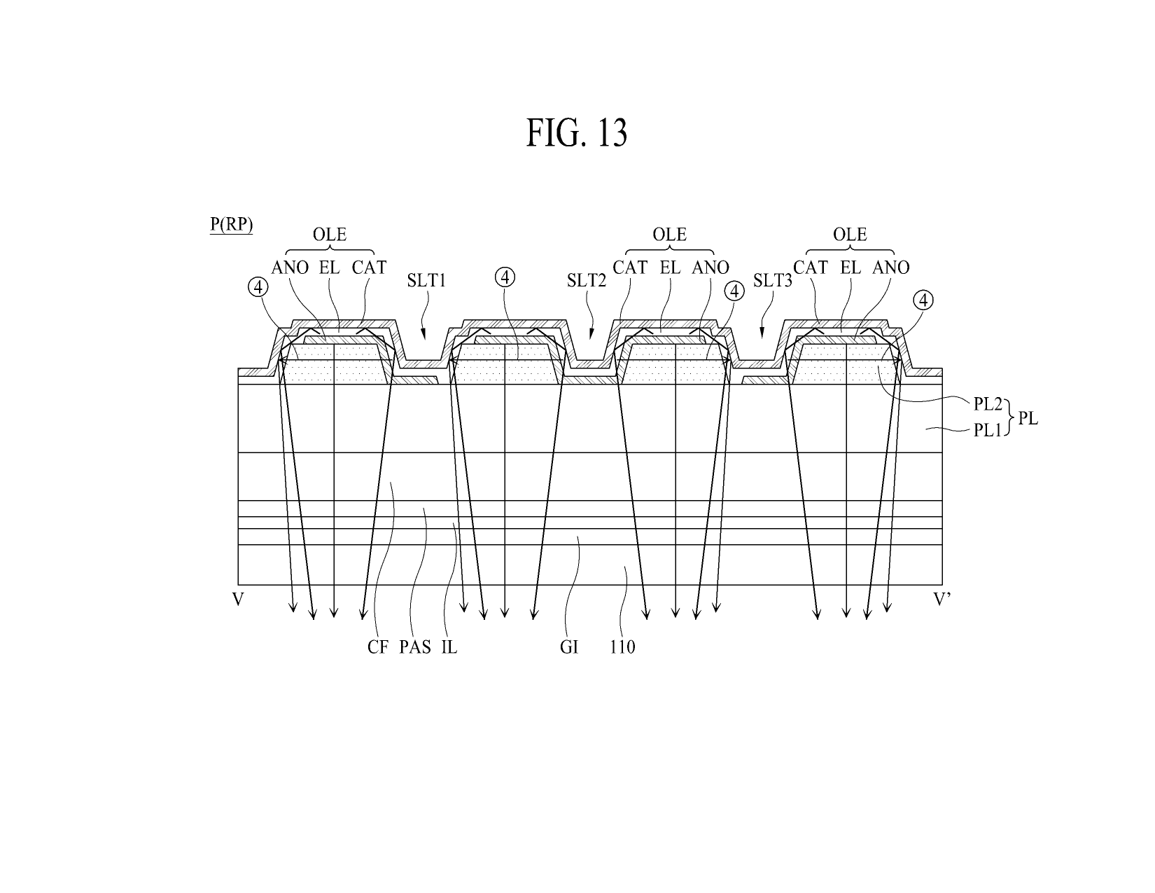

Hereinafter, referring to FIG. 12 and FIG. 13, a light emitting display device according to the fifth embodiment will be explained. FIG. 12 is an enlarged plan view illustrating a structure of a light emitting display device according to the fifth embodiment of the present disclosure. FIG. 13 is an enlarged cross-sectional view, taken along line V-V’ of FIG. 12, illustrating a structure of a light emitting display device according to the fifth embodiment of the present disclosure.

Referring to FIG. 12, a light emitting display device according to the fifth embodiment of the present disclosure can include a pixel P having a rectangular shape of which vertical length along Y-axis is longer than the lateral length along X-axis. In particular, at the middle portion of the pixel P (or middle portion of the anode electrode ANO), three slits SLT can be disposed. Each of the slit SLT has a rectangular shape of which lateral side length along X-axis is longer than the vertical side width along Y-axis. A side having the lateral length of each slit SLT can be parallel to the upper side of the pixel P between the upper side and the lower side of the pixel P. For example, a first slit SLT1, a second slit SLT2 and a third slit SLT3 can be disposed as being separated with a predetermined distance (or gap).

Even though FIG. 12 shows the red pixel RP, other pixels can include the same slits SLT as the red pixel RP. The structures of other portions of the pixel P except the slit SLT can be the same as the pixel P described with FIG. 3, so the same explanation will not be duplicated.

Referring to FIG. 13, the light emitting display device according to the fifth embodiment can include a gate insulating layer GI, an intermediate insulating layer IL and a passivation layer PAS sequentially stacked on a substrate 110. A color filter CF can be disposed on the passivation layer PAS. A planarization layer PL can be disposed on the color filter CF.

The planarization layer PL can include a first planarization layer PL1 and a second planarization layer PL2. The first planarization layer PL1 can be disposed over entire surface of the pixel P, and the second planarization layer PL2 can be disposed within emission area of the pixel P. The second planarization layer PL2 can have an island shape extruded (or protruded) on the upper surface of the first planarization layer PL1. The upper surface of the second planarization layer PL2 can be disposed at higher position than the upper surface of the first planarization layer PL1.

The slit SLT can include a first slit SLT1, a second slit SLT2 and a third slit SLT3. Therefore, the second planarization layer PL2 can have four regions in the pixel P divided by the first slit SLT1, the second slit SLT2 and the third slit SLT3. However, referring to FIG. 12, at the left side portion and the right side portion of the pixel P, the second planarization layer PL2 may not be divided by the first slit SLT1, the second slit SLT2 and the third slit SLT3. For example, the second planarization layer PL2 can be continuously disposed at the left side and the right side of the pixel P. The bottom surfaces of the first slit SLT1, the second slit SLT2 and the third slit SLT3 can be disposed at slightly higher position than the upper surface of the first planarization layer PL1. For this case, the first planarization layer PL1 may not be exposed by the first slit SLT1, the second slit SLT2 and the third slit SLT3. The bottom surfaces of the first slit SLT1, the second slit SLT2 and the third slit SLT3 can be corresponding to a bottom surface formed by recessing the second planarization layer PL2. For another example, the bottom surfaces of the first slit SLT1, the second slit SLT2 and the third slit SLT3 can be disposed inward of the first planarization layer PL1 formed by further etching the first planarization layer PL1 from the upper surface of the first planarization layer PL1.

An anode electrode ANO can be disposed on the upper surface of the second planarization layer PL2. Further, the anode electrode ANO can be disposed at the bottom surfaces of the first slit SLT1, the second slit SLT2 and the third slit SLT. As shown in FIG. 12, on the plan view, the first slit SLT1, the second slit SLT2 and the third slit SLT3 can be disposed as being apart from the left side and right side with the predetermined distances, respectively, within inside area of the anode electrode ANO. Therefore, entire portions of the anode electrode ANO can be electrically connected within a pixel P.

For example, the anode electrode ANO can be disposed at the bottom surface of the first slit SLT1, extending along the left etched side wall of the first slit SLT1 formed at the second planarization layer PL2, and then reaching to the upper surface of the second planarization layer PL2. Further, the anode electrode ANO can be disposed at the bottom surface of the second slit SLT2, extending along the right etched side wall and the left etched side wall of the second slit SLT2 formed at the second planarization layer PL2, and then reaching to the upper surface of the second planarization layer PL2. The anode electrode ANO can be disposed at the bottom surface of the third slit SLT3, extending along the right etched side wall of the third slit SLT3 formed at the second planarization layer PL2, and then reaching to the upper surface of the second planarization layer PL2.

An emission layer EL can be disposed on the first planarization layer PL1, the second planarization layer PL2 and the anode electrode ANO. A cathode electrode CAT can be disposed on the emission layer EL. The cathode electrode CAT can be in surface contact with the emission layer EL. Therefore, the emission layer EL and the cathode electrode CAT can be stacked along the cross-sectional profile of the first planarization layer PL1 and the second planarization layer PL2. Accordingly, at the step different portions of the first planarization layer PL1 and the second planarization layer PL2, the cathode electrode CAT can form a micro-mirror structure. In particular, each of the four regions of the second planarization layer PL2 divided by the first slit SLT1, the second slit SLT2 and the third slit SLT3 can have micro-mirror, so the light emitting display device according to the fifth embodiment can include four micro mirror structures, within the pixel P.

The second planarization layer PL2 can have higher refractive index than the first planarization layer PL1. For example, the anode electrode can have a refractive index of 2.0 to 2.3. The second planarization layer PL2 can have a refractive index of 1.8 to 2.0 which is same as that of the anode electrode ANO or with 0.2 different from that of the anode electrode ANO. Meanwhile, the first planarization layer PL1 can be made of a transparent organic material having a refractive index of 1.3 to 1.5, which is at least 0.5 lower than that of the second planarization layer PL2.

The lights generated from the emission layer EL can have a light emitting path based on the same mechanism as explained in the fourth embodiment. Therefore, the optical path of the light is shown as arrow line in FIG. 13.

In the fifth embodiment, as the anode electrode ANO has a shape in which vertical length is longer than the lateral length, the path length of the lights propagated from the middle portion of the light emitting diode OLE to the upper side or the lower side by the total reflection can be longer than the path length of the lights propagated from the middle portion of the light emitting diode OLE to the left side or the right side by the total reflection. Therefore, the lights propagated in vertical direction (along Y-axis) by total reflection can be lost into heat energy more than the lights propagated in horizontal direction (along X-axis). Accordingly, in the fifth embodiment, by arraying a plurality of slits SLT that are longer in size in the lateral direction than the vertical direction, the amount of the lights lost by total reflection can be minimized, so the light extraction efficiency can be enhanced.

The light emitting display device according to the fifth embodiment, the lights generated from the emission layer EL can be extracted by the cathode electrode CAT having the micro-mirror structure formed by the second planarization layer PL2 extruded as an island shape, so the light extraction efficiency can be increased. In particular, as the second planarization layer PL2 can have a refractive index the same as or slightly less than the anode electrode ANO, the amount of trapped lights inside the light emitting diode OLE can be minimized, so the light extraction efficiency can be enhanced.

Further, in the light emitting display device according to the fifth embodiment, the anode electrode ANO can be disposed as starting from the upper surface of the second planarization layer PL2, extending along the sidewalls of the first slit SLT1, the second slit SLT2 and the third slit SLT3, and then to the bottom surfaces of the first slit SLT1, the second slit SLT2 and the third slit SLT3. Therefore, the first slit SLT1, the second slit SLT2 and the third slit SLT3 can have the light emitting diode OLE. Accordingly, the first slit SLT1, the second slit SLT2 and the third slit SLT3 can be included into the emission area.

In addition, the anode electrode ANO, the emission layer EL and the cathode electrode CAT can be stacked at the sidewall of the first slit SLT1, the second slit SLT2 and the third slit SLT3 to form the light emitting diode OLE. For example, the light can be generated from the sidewall of the first slit SLT1, the second slit SLT2 and the third slit SLT3.

The light generated from the sidewalls of the first slit SLT1, the second slit SLT2 and the third slit SLT3 can pass through the second planarization layer PL2, and propagate to the opposite sidewall of the second planarization layer PL2. The sidewall of the second planarization layer PL2 can have the cathode electrode CAT so it can form the micro-mirror structure. Therefore, the lights generated from the sidewall of the first slit SLT1, the second slit SLT2 and the third slit SLT3 can be reflected by the micro-mirror structure so emitted out of the substrate 110, shown as the optical path ④ in FIG. 13.

Further, by forming a slit SLT at the middle portion of the second planarization layer PL2, a plurality of micro-mirror structures having the length or width smaller than the length or width of the pixel can be formed. As a result, it can be configured so that lights generated from the emission layer EL is extracted to the outside by the micro-mirror structure between the anode electrode ANO and the second planarization layer PL2 before being trapped inside the light emitting diode OLE due to total reflection conditions and lost as heat energy.

In the descriptions from the first embodiment to the fifth embodiment and other examples of the present disclosure, the light emitting display device can have a bankless structure in which the bank for defining the emission area by covering the circumferential edges of the anode electrode ANO is not formed. Here, the bank can be an insulating layer for defining the emission area by covering the circumferential edges of the anode electrode ANO to expose the middle portion of the anode electrode ANO. The bank can be called the pixel defining layer. The light emitting display device according to the present disclosure may not have bank at all. However, it is not limited thereto, the bank can be disposed at the upper side and lower side of the pixel where the driving element is disposed, excepting the left side and the right side of the pixel. Further, for the case of having bank surrounding the pixel, the structure described in the present disclosure can be applied. The present disclosure mainly describes the bankless structure that can be advantageous for low-power operation and can ensure the maximum aperture ratio.

Various features of the light emitting display device according to one or more examples of the present disclosure can be described as follows.

A light emitting display device according to examples of the present disclosure can include a substrate, a plurality of pixels on the substrate, a first planarization layer on the substrate, a second planarization disposed on the first planarization, a slit, an anode electrode, an emission layer and a cathode electrode. Each of the pixels has an emission area and a non-emission area. The second planarization layer is disposed at the emission area. The slit is disposed at a middle portion of the second planarization layer. The slit is formed by depressing down from a upper surface of the second planarization layer. The anode electrode is disposed on the upper surface of the second planarization layer and a bottom surface of the slit. The emission layer is on the anode electrode, the first planarization layer and the second planarization layer. The cathode electrode is on the emission layer.

In an example, the emission layer covers an upper surface of the first planarization layer, a sidewall of the second planarization layer and an upper surface of the anode electrode. The cathode electrode is in surface contact with the emission layer.

In an example, the light emitting display device further comprises a color filter disposed under the first planarization layer on the substrate, and a driving element layer disposed under the color filter on the substrate.

In an example, the slit can include the bottom surface, a first sidewall disposed at a first side of the bottom surface and a second sidewall disposed at a second side of the bottom surface facing the first side.

In an example, the slit exposes the upper surface of the first planarization layer.

In an example, the anode electrode is disposed starting from on the upper surface of the second planarization layer, extending through the first sidewall of the slit and reaching to the bottom surface of the slit.

In an example, lights generated from the emission layer disposed at the first sidewall of the slit on the anode electrode passes through the second planarization layer, is reflected by the cathode electrode facing the first sidewall and then passes through the first planarization layer and then is radiated out of the substrate.

In an example, each of the pixels can include a first side having a first length along a lateral direction; a second side having the first length and being parallel to the first side; a third side having a second length longer than the first length along a vertical direction; and a fourth side having the second length and being parallel to the third side.

In an example, the slit has a rectangular shape of which a vertical length is longer than a lateral width, and is disposed as a side having the vertical length being parallel to the first side of the pixel between the first side and the second side.

In an example, the slit has a plurality of sub-slits arrayed with a predetermined gap between the first side and the second side.

In an example, the slit has a rectangular shape of which a lateral length is longer than a vertical width, and is disposed as a side having the lateral length being parallel to the third side of the pixel between the third side and the fourth side.

In an example, the slit has a plurality of sub-slits arrayed with a predetermined gap between the third side and the fourth side.

In an example, the first planarization layer and the second planarization layer include a material having a same refractive index.

In an example, the first planarization layer includes a first transparent insulating material having a first refractive index. The second planarization layer includes a second transparent insulating material having a second refractive index greater than the first refractive index.

The various embodiments of the present disclosure described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments of the present disclosure can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the disclosure and the claims, but should be construed to include all possible embodiments along with the full scope of equivalents to which such claims are entitled. Accordingly, the claims are not limited by the detailed description.

What is claimed is:

1. A light emitting display device comprising:
a substrate;
a plurality of pixels arranged on the substrate, each of the plurality of pixels having an emission area and a non-emission area;
a first planarization layer disposed on the substrate;
a second planarization layer disposed at the emission area on the first planarization layer;
a slit disposed at a middle portion of the second planarization layer, the slit defined by an upper surface of the second planarization layer that is depressed downwardly;
an anode electrode disposed on the upper surface of the second planarization layer and a bottom surface of the slit;
an emission layer disposed on the anode electrode, the first planarization layer and the second planarization layer; and
a cathode electrode disposed on the emission layer.

2. The light emitting display device according to claim 1, wherein the emission layer covers an upper surface of the first planarization layer, a sidewall of the second planarization layer and an upper surface of the anode electrode, and
wherein the cathode electrode is in surface contact with the emission layer.

3. The light emitting display device according to claim 1, further comprising:
a color filter disposed under the first planarization layer on the substrate; and
a driving element layer disposed under the color filter on the substrate.

4. The light emitting display device according to claim 1, wherein the slit includes:
the bottom surface;
a first sidewall disposed at a first side of the bottom surface; and
a second sidewall disposed at a second side of the bottom surface facing the first side of the bottom surface.

5. The light emitting display device according to claim 4, wherein the slit exposes an upper surface of the first planarization layer.

6. The light emitting display device according to claim 5, wherein the anode electrode is disposed starting from on the upper surface of the second planarization layer, extending through the first sidewall of the slit and reaching to the bottom surface of the slit.

7. The light emitting display device according to claim 6, wherein light generated from the emission layer disposed at the first sidewall of the slit on the anode electrode passes through the second planarization layer, is reflected by the cathode electrode facing the first sidewall of the slit, passes through the first planarization layer, and then is radiated out of the substrate.

8. The light emitting display device according to claim 1, wherein each of the plurality of pixels includes:
a first side having a first length along a lateral direction;
a second side having the first length and being parallel to the first side;
a third side having a second length longer than the first length along a vertical direction; and
a fourth side having the second length and being parallel to the third side.

9. The light emitting display device according to claim 8, wherein the slit has a rectangular shape of which a vertical length is longer than a lateral width, and is disposed as a side having the vertical length being parallel to the first side of a pixel among the plurality of pixels between the first side and the second side.

10. The light emitting display device according to claim 9, wherein the slit has a plurality of sub-slits arrayed with a predetermined gap between the first side and the second side of the pixel.

11. The light emitting display device according to claim 8, wherein the slit has a rectangular shape of which a lateral length is longer than a vertical width, and is disposed as a side having the lateral length being parallel to the third side of a pixel among the plurality of pixels between the third side and the fourth side.

12. The light emitting display device according to claim 11, wherein the slit has a plurality of sub-slits arrayed with a predetermined gap between the third side and the fourth side of the pixel.

13. The light emitting display device according to claim 1, wherein the first planarization layer and the second planarization layer include a material having a same refractive index.

14. The light emitting display device according to claim 1, wherein the first planarization layer includes a first transparent insulating material having a first refractive index, and
wherein the second planarization layer includes a second transparent insulating material having a second refractive index greater than the first refractive index.

15. The light emitting display device according to claim 14, wherein the first refractive index is at least 0.5 lower than the second refractive index.

16. The light emitting display device according to claim 1, wherein the second planarization layer has an island shape protruding on an upper surface of the first planarization layer.

17. The light emitting display device according to claim 1, wherein the bottom surface of the slit is located under an upper surface of the first planarization layer.

18. The light emitting display device according to claim 1, wherein the second planarization has a refractive index that is same as the anode electrode or lower than the anode electrode.

19. The light emitting display device according to claim 10, wherein the plurality of sub-slits are included in the emission area.

20. The light emitting display device according to claim 1, wherein light generated from sidewalls of the slit passes through the second planarization layer, and propagates to an opposite sidewall of the second planarization layer, and
wherein sidewalls of the second planarization layer are disposed with the cathode electrode.
